(19) United States
(12) Patent Application Publication
(10) Pub. No.: US 2026/0052764 A1
(43) Pub. Date: Feb. 19, 2026

(54) Semiconductor device including contact structure with extra isolation layer thereon

(71) Applicant: SAMSUNG ELECTRONICS CO., LTD., Suwon-si (KR)

(72) Inventors: Inwon PARK, Niskayuna, NY (US); Wonkeun CHUNG, Clifton Park, NY (US); Kang-ill SEO, Springfield, VA (US)

(73) Assignee: SAMSUNG ELECTRONICS CO., LTD., Suwon-si (KR)

(21) Appl. No.: 19/054,502

(22) Filed: Feb. 14, 2025

Related U.S. Application Data
(60) Provisional application No. 63/683,054, filed on Aug. 14, 2024.

(51) Int. Cl. H10D 84/83; H10D 30/00; H10D 30/01; H10D 30/43; H10D 62/10; H10D 62/13; H10D 64/23; H10D 84/01

(52) U.S. Cl. CPC H10D 84/832; H10D 30/014; H10D 30/019; H10D 30/43; H10D 30/502; H10D 62/121; H10D 62/151; H10D 64/256; H10D 84/0149; H10D 84/0151; H10D 84/8311; H10D 84/8312

(57) ABSTRACT

Provided is a semiconductor device which includes: an isolation structure; a 1^{st} contact structure in the isolation structure; and a 2^{nd} contact structure adjacent to and at a lateral side of the 1^{st} contact structure, in the isolation structure, wherein at least one of the 1^{st} contact structure and the 2^{nd} contact structure has an extra isolation layer on a side surface thereof facing the other of the 1^{st} contact structure and the 2^{nd} contact structure.

### CROSS-REFERENCE TO RELATED APPLICATION

This application is based on and claims priority from U.S. Provisional Application No. 63/683,054 filed on Aug. 14, 2024 in the U.S. Patent and Trademark Office, the disclosure of which is incorporated herein in its entirety by reference.

### BACKGROUND

### 1. Field

Apparatuses and methods consistent with the disclosure relate to a stacked semiconductor device in which a contact structure which is self-aligned on a source/drain pattern.

### 2. Description of Related Art

A stacked field-effect transistor (FET) device has been introduced in a response to increased demand for a semiconductor device having a high device density and performance.

The stacked FET device may include a lower FET and an upper FET vertically thereabove, where each of the two FETs may be a fin field-effect transistor (FinFET), a nanosheet transistor, a forksheet transistor, or any other types of FET.

The FinFET has one or more fin structures, which are protruded from a substrate, as a channel structure and a gate structure surrounding at least three surfaces of each of the fin structures. The nanosheet transistor is characterized by one or more nanosheet channel layers, which are vertically stacked or arranged on a substrate, as a channel structure and a gate structure surrounding all four surfaces of each of the nanosheet channel layers. The nanosheet transistor is referred to as a gate-all-around (GAA) transistor or a multi-bridge channel field-effect transistor (MBCFET). The forksheet transistor is a combination of two nanosheet transistors with an isolation wall therebetween. In the forksheet transistor, nanosheet channel layers of each nanosheet transistor are formed at each side of the isolation wall and pass through a gate structure in parallel with the isolation wall.

The stacked FET device may be implemented in a standard cell and manufactured based on the layout of the semiconductor cell. However, as the cell height of the standard cell including the stacked FET device become smaller and smaller to respond to the increased demand for high-density semiconductor devices, formation of contact structures connecting source/drain patterns of the stacked FET device to a back-end-of-line (BEOL) structures such as metal lines exposes various risks including a short circuit between the contact structures and increased contact resistance.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

The disclosure provides a contact structure which takes a form of pillar similar to a via structure and has an extra isolation layer formed on a side surface thereof. This contact structure may be a contact structure formed on a top surface of a source/drain pattern such as a lower source/drain pattern of an FET of a stacked FET device. The contact structure with the extra isolation layer may provide an additional secure isolation with respect to an adjacent structural element such as a source/drain pattern and a contact structure on the source/drain pattern.

According to an aspect of the disclosure, there is provided a semiconductor device which may include: an isolation structure; a 1^{st} contact structure in the isolation structure; and a 2^{nd} contact structure adjacent to and at a lateral side of the 1^{st} contact structure, in the isolation structure, wherein at least one of the 1^{st} contact structure and the 2^{nd} contact structure has an extra isolation layer on a side surface thereof facing the other of the 1^{st} contact structure and the 2^{nd} contact structure.

According to an aspect of the disclosure, there is provided a semiconductor device which may include: an isolation structure; and a contact structure with an extra isolation layer on a side surface thereof, in the isolation structure. The contact structure may include a 1^{st} portion; and a 2^{nd} portion vertically above the 1^{st} portion, wherein the extra isolation layer is not formed on a side surface of the 1^{st} portion.

According to an aspect of the disclosure, there is provided a method of manufacturing a semiconductor device, which may include: forming an isolation structure; forming a 1^{st} contact structure in the isolation structure; and forming a 2^{nd} contact structure adjacent to and at a lateral side of the 1^{st} contact structure, in the isolation structure, wherein at least one of the 1^{st} contact structure and the 2^{nd} contact structure is formed to have an extra isolation layer on a side surface thereof facing the other of the 1^{st} contact structure and the 2^{nd} contact structure.

### BRIEF DESCRIPTION OF DRAWINGS

Example embodiments of the disclosure will be more clearly understood from the following detailed description taken in conjunction with the accompanying drawings.

FIGS. 1A-1C illustrate a stacked FET device in which a 2^{nd} FET vertically stacked on a 1^{st} FET is formed to have a smaller width than the 1^{st} FET, according to one or more embodiments.

FIG. 2A illustrates a stacked FET device in which a 2^{nd} FET vertically stacked on a 1^{st} FET is formed to have a smaller width than the 1^{st} FET, and contact structures are surrounded by extra isolation layers, according to one or more embodiments, and FIG. 2B illustrates the stacked FET device of FIG. 2A in which contact structures surrounded by extra isolation layers are misaligned with source/drain patterns, according to one or more embodiments.

FIG. 3A illustrates a stacked FET device in which a 2^{nd} FET vertically stacked on a 1^{st} FET is formed to have a smaller width than the 1^{st} FET, contact structures are surrounded by extra isolation layers, and an extra metal structure is formed at a lower portion of one of the contact structures, according to one or more embodiments, and FIG. 3B illustrates the stacked FET device of FIG. 3A in which contact structures surrounded by extra isolation layers are misaligned with source/drain patterns, according to one or more embodiments.

FIGS. 4A-4H illustrate intermediate semiconductor devices obtained after respective steps of manufacturing a stacked FET device in which a 2^{nd} FET vertically stacked on a 1^{st} FET is formed to have a smaller width than the 1^{st} FET, and contact structures are surrounded by extra isolation layers, according to one or more embodiments.

FIGS. 5A-5F illustrate intermediate semiconductor devices obtained after respective steps of manufacturing a stacked FET device in which a 2^{nd} FET vertically stacked on a 1^{st} FET is formed to have a smaller width than the 1^{st} FET, contact structures are surrounded by extra isolation layers, and an extra metal structure is formed at a lower portion of one of the contact structures, according to one or more embodiments.

FIG. 6 is a flowchart of manufacturing a stacked FET device in which a 2^{nd} FET vertically stacked on a 1^{st} FET is formed to have a smaller width than the 1^{st} FET, and contact structures are surrounded by extra isolation layers, according to one or more embodiments.

FIG. 7 is a flowchart of manufacturing a stacked FET device in which a 2^{nd} FET vertically stacked on a 1^{st} FET is formed to have a smaller width than the 1^{st} FET, contact structures are surrounded by extra isolation layers, and an extra metal structure is formed at a lower portion of one of the contact structures, according to one or more embodiments.

FIG. 8 is a schematic block diagram illustrating an electronic device including one or more stacked FET devices shown in FIGS. 1A-1C, 2A-2B and 3A-3B, according to one or more embodiments.

### DETAILED DESCRIPTION

All of the embodiments of the disclosure described herein are example embodiments, and thus, the disclosure is not limited thereto, and may be realized in various other forms. Each of the embodiments provided in the following description is not excluded from being associated with one or more features of another example or another embodiment also provided herein or not provided herein but consistent with the disclosure. For example, even if matters described in a specific example or embodiment are not described in a different example or embodiment thereto, the matters may be understood as being related to or combined with the different example or embodiment, unless otherwise mentioned in descriptions thereof. In addition, it should be understood that all descriptions of principles, aspects, examples, and embodiments of the disclosure are intended to encompass structural and functional equivalents thereof. In addition, these equivalents should be understood as including not only currently well-known equivalents but also equivalents to be developed in the future, that is, all devices invented to perform the same functions regardless of the structures thereof. For example, channel layers, sacrificial layers, and isolation layers described herein may take a different type or form as long as the disclosure can be applied thereto.

It will be understood that when an element, component, layer, pattern, structure, region, or so on (hereinafter collectively “element”) of a semiconductor device is referred to as being “over,” “above,” “on,” “below,” “under,” “beneath,” “connected to” or “coupled to” another element of the semiconductor device, it can be directly over, above, on, below, under, beneath, connected or coupled to the other element or an intervening element(s) may be present. In contrast, when an element of a semiconductor device is referred to as being “directly over,” “directly above,” “directly on,” “directly below,” “directly under,” “directly beneath,” “directly connected to” or “directly coupled to” another element of the semiconductor device, there are no intervening elements present. Like numerals refer to like elements throughout this disclosure.

Spatially relative terms, such as “over,” “above,” “on,” “upper,” “below,” “under,” “beneath,” “lower,” “left,” “right,” “lower-left,” “lower-right,” “upper-left,” “upper-right,” “central,” “middle,” and the like, may be used herein for ease of description to describe one element's relationship to another element(s) as illustrated in the figures. It will be understood that the spatially relative terms are intended to encompass different orientations of a semiconductor device in use or operation in addition to the orientation depicted in the figures. For example, if the semiconductor device in the figures is turned over, an element described as “below” or “beneath” another element would then be oriented “above” the other element. Thus, the term “below” can encompass both an orientation of above and below. The semiconductor device may be otherwise oriented (rotated 90 degrees or at other orientations) and the spatially relative descriptors used herein interpreted accordingly. As another example, when elements referred to as a “left” element and a “right” element” may be a “right” element and a “left” element when a device or structure including these elements are differently oriented. Thus, in the descriptions herebelow, the “left” element and the “right” element may also be referred to as a “1^{st}” element or a “2^{nd}” element, respectively, as long as their structural relationship is clearly understood in the context of the descriptions. Similarly, the terms a “lower” element and an “upper” element may be respectively referred to as a “1^{st}” element and a “2^{nd}” element with necessary descriptions to distinguish the two elements.

It will be understood that, although the terms “1^{st},” “2^{nd},” “3^{rd},” “4^{th},” “5^{th},” “6^{th},” etc. may be used herein to describe various elements, these elements should not be limited by these terms. These terms are only used to distinguish one element from another element. Thus, a 1^{st} element described in the descriptions of an embodiments could be termed a 2^{nd} element in the descriptions of another element or one or more claims, and vice versa without departing from the teachings of the disclosure.

As used herein, expressions such as “at least one of,” when preceding a list of elements, modify the entire list of elements and do not modify the individual elements of the list. For example, the expression, “at least one of a, b and c,” should be understood as including only a, only b, only c, both a and b, both a and c, both b and c, or all of a, b and c.

In the descriptions herein, the terms of degree including “substantially” or “about” may be used. In one or more examples, when specifying that a parameter X may be substantially the same as parameter Y, the term “substantially” may be understood as X being within 10% of Y. In one or more examples, when specifying that a parameter is about X, the term “about” may be understood as being within 10% of X. Still, when a term “same” is used to compare parameters of two or more elements, the term may cover “substantially same” parameters.

It will be understood that, when the term “contact” is used to describe two metal elements, for example, a metal line and a via structure, a barrier metal layer such as titanium (Ti), tantalum (Ta), titanium nitride (TiN), tantalum nitride (TaN), tungsten nitride (WN), nickel nitride (NiN), cobalt nitride (CoN), or platinum nitride (PtN), not being limited thereto, may be formed therebetween. Further, it will be understood that, when a metal contract structure is described as being formed on or contact a surface of a source/drain pattern, a silicide layer such as cobalt silicide (CoSi₂), nickel silicide (NiSi₂), titanium silicide (TiSi), or tungsten silicide (WSi₂), not being limited thereto, may be formed therebetween.

It will be also understood that, even if a certain step or operation of manufacturing an apparatus or structure is described later than another step or operation, the step or operation may be performed later than the other step or operation unless the other step or operation is described as being performed after the step or operation.

Many embodiments are described herein with reference to cross-sectional views that are schematic illustrations of the embodiments (and intermediate structures). As such, variations from the shapes of the illustrations as a result, for example, of manufacturing techniques and/or tolerances, are to be expected. Thus, the embodiments should not be construed as limited to the particular shapes of regions illustrated herein but are to include deviations in shapes that result, for example, from manufacturing. Various regions illustrated in the figures are schematic in nature and their shapes are not intended to illustrate the actual shape of a region of a device and are not intended to limit the scope of the disclosure. Further, in the drawings, the sizes and relative sizes of layers and regions may be exaggerated for clarity.

For the sake of brevity, conventional elements, structures or layers of semiconductor devices including a nanosheet transistor and materials forming the same may or may not be described in detail herein. For example, a certain isolation layer or structure of a semiconductor device and materials forming the same may be omitted herein when this layer or structure is not related to the novel features of the embodiments. Also, descriptions of materials forming well-known structural elements of a semiconductor device may be omitted herein when those materials are not relevant to the novel features of the embodiments. Herein, the term “isolation” pertains to electrical insulation or separation between structures, layers, components or regions in a corresponding device or structure.

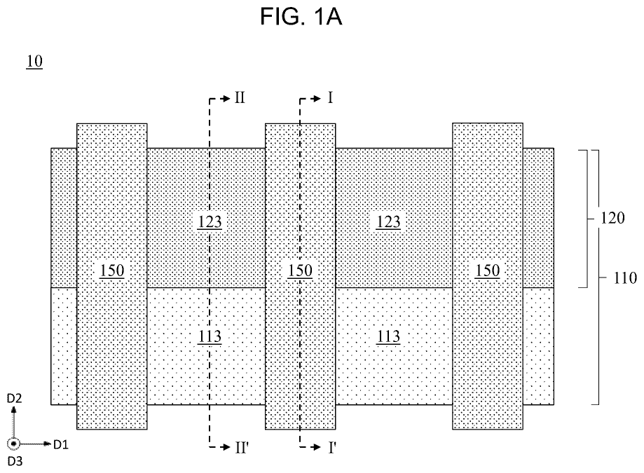

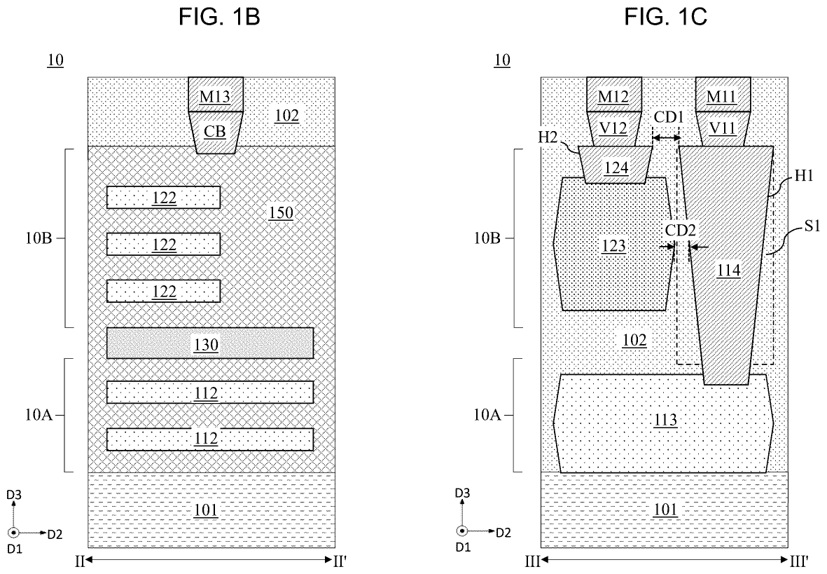

FIGS. 1A-1C illustrate a stacked FET device in which a 2^{nd} FET vertically stacked on a 1^{st} FET is formed to have a smaller width than the 1^{st} FET, according to one or more embodiments.

FIG. 1A is a plan view of a stacked FET device 10, and FIGS. 1B and 1C are cross-section views of the stacked FET device shown in FIG. 1A taken along lines I-I′ and II-II′, respectively. It is to be understood that FIG. 1A is provided to show positional relationships between structural elements of the stacked FET devices such as active patterns and gate structure, and thus, some structural elements such as an isolation structure, metal lines and via structures may not be shown therein for brevity purposes.

Referring to FIG. 1A, the stacked FET device 10 may include a 1^{st} active pattern 110 and a 2^{nd} active pattern 120 extended in a D1 direction and arranged in a D2 direction intersecting the D1 direction. The 2^{nd} active pattern 120 may be stacked on the 1^{st} active pattern 110 in a D3 direction intersecting the D1 and D2 directions, and may have a smaller width than the 1^{st} active pattern 110 in the D2 direction. Thus, the 1^{st} active pattern 110 may be partially overlapped by the 2^{nd} active pattern 120 in the D3 direction. The stacked FET device 10 may also include a plurality of gate structures 150 arranged in the D1 direction and extended in the D2 direction across the active patterns 110 and 120.

The D1 direction refers to a channel-length direction in which a current flows between two source/drain patterns of an FET connected to each other through a channel structure of the FET, the D2 direction is a channel-width direction or a cell-height direction, and the D3 direction is a channel-thickness direction. The D1 and D2 directions may each be referred to as a horizontal direction and the D3 direction may be referred to as a vertical direction.

Referring to FIGS. 1A-1C, the stacked FET device 10 may include a 1^{st} FET 10A formed on a base layer 101 and a 2^{nd} FET 10B formed vertically above the 1^{st} FET 10A. The base layer 101 may be a silicon (Si)-based substrate. However, when a backside power delivery network (BSPDN) is formed on a back side of the stacked FET device 10, the base layer 101 may include a backside isolation structure formed of a low-k dielectric material such as silicon oxide (e.g., SiO₂).

The 1^{st} FET 10A and the 2^{nd} FET 10B may be respectively formed based on the 1^{st} active pattern 110 and the 2^{nd} active pattern 120 stacked thereon along with a corresponding gate structure 150. The 1^{st} active pattern 110 may form a 1^{st} channel structure 112 and 1^{st} source/drain patterns 113 for the 1^{st} FET 10A at a 1^{st} level, and the 2^{nd} active pattern 120 may form a 2^{nd} channel structure 122 and 2^{nd} source/drain patterns 123 for the 2^{nd} FET 10B at a 2^{nd} level vertically above the 1^{st} level.

The 1^{st} channel structure 112 of the 1^{st} FET 10A may include a plurality of 1^{st} nanosheet layers epitaxially grown from a silicon (Si)-based substrate therebelow, and thus, the 1^{st} nanosheet layers may also be formed of silicon. The 1^{st} source/drain patterns 113 may be epitaxially grown from the 1^{st} nanosheet layers of the 1^{st} channel structure 112, and may be formed of silicon (Si) or silicon germanium (SiGe) doped with impurities. When the 1^{st} FET 10A is to form an n-type field-effect transistor (NFET), the 1^{st} source/drain patterns 113 may be formed of silicon (Si) doped with n-type impurities such as phosphorus (P), arsenic (As), or antimony (Sb). In contrast, when the 1^{st} FET 10A is to form a p-type field-effect transistor (PFET), the 1^{st} source/drain patterns 113 may be formed of silicon germanium (SiGe) doped with p-type impurities such as boron (B), gallium (Ga), or indium (In).

The 1^{st} channel structure 112 may be surrounded by a gate structure 150 which controls current flow between the 1^{st} source/drain patterns 113 through the 1^{st} channel structure 112. The gate structure 150 may include a gate dielectric layer surrounding the 1^{st} nanosheet layers, a 1^{st} work-function metal layer formed on the gate dielectric layer, and a gate electrode formed on the work-function metal layer. Thus, the 1^{st} channel structure 112 including the 1^{st} nanosheet layers, the 1^{st} source/drain patterns 113 and the gate structure 150 may form the 1^{st} FET 10A implemented by a nanosheet transistor at the 1^{st} level of the stacked FET device 10.

The 2^{nd} channel structure 122 of the 2^{nd} FET 10B may include a plurality of 2^{nd} nanosheet layers which are epitaxially grown from the silicon (Si)-based substrate along with the 1^{st} nanosheet layers of the 1^{st} channel structure 112, and thus, the 2^{nd} nanosheet layers may also be formed of silicon. The 2^{nd} source/drain patterns 123 may be epitaxially grown from the 2^{nd} nanosheet layers of the 2^{nd} channel structure 122, and may also be formed of silicon (Si) or silicon germanium (SiGe) doped with impurities. When the 2^{nd} FET 10B is to form a PFET, the 2^{nd} source/drain patterns 123 may be formed of silicon germanium (SiGe) doped with p-type impurities such as boron (B), gallium (Ga), or indium (In). In contrast, when the 2^{nd} FET 10B is to form an NFET, the 2^{nd} source/drain patterns 123 may be formed of silicon (Si) doped with n-type impurities such as phosphorus (P), arsenic (As), or antimony (Sb).

The 2^{nd} channel structure 122 may also be surrounded by the gate structure 150 which controls current flow between the 2^{nd} source/drain patterns 123 through the 2^{nd} channel structure 122. The gate dielectric layer surrounding the 1^{st} channel structure 112 may be extended to also surround the 2^{nd} channel structure 122, and a 2^{nd} work-function metal layer may be formed on this gate dielectric layer, and further, the gate electrode on the 1^{st} work-function metal layer may also be extended to surround the 2^{nd} work-function metal layer. Thus, the 2^{nd} channel structure 122 including the 2^{nd} nanosheet layers, the 2^{nd} source/drain patterns 123 and the gate structure 150 may form the 2^{nd} FET 10B implemented by a nanosheet transistor at the 2^{nd} level of the stacked FET device 10.

A middle dielectric isolation (MDI) structure 130 may be formed in the stacked FET device 10 to isolate the 1^{st} FET 10A from the 2^{nd} FET 10B.

As described earlier, the 2^{nd} active pattern 120 is formed to have a smaller width in the D2 direction than the 1^{st} active pattern 110. Accordingly, the 2^{nd} nanosheet layers forming the 2^{nd} channel structure 122 of the 2^{nd} FET 10B may have a smaller width in the D2 direction than the 1^{st} nanosheet layers forming the 1^{st} channel structure 112 of the 1^{st} FET 10A, and the 2^{nd} channel structure 122 may only partially overlap the 1^{st} channel structure 112 in the D3 direction. For example, right side surfaces of the 2^{nd} nanosheet layers may aligned or coplanar with right side surfaces of the 1^{st} nanosheet layers in the D3 direction, while left side surfaces of the 2^{nd} nanosheet layers are not aligned or coplanar with left side surfaces of the 1^{st} nanosheet layers in the D3 direction.

Due to this width difference between the channel structures 112 and 122, a 2^{nd} source/drain pattern 123 epitaxially grown from the 2^{nd} nanosheet layers may also be formed to have a smaller width in the D2 direction than a 1^{st} source/drain pattern 113 formed epitaxially grown from the 1^{st} nanosheet layers to be disposed vertically below the 2^{nd} source/drain pattern 123. This width difference between the source/drain patterns 113 and 123 provides a space S1 above a top surface of the 1^{st} source/drain pattern 113 which is not vertically overlapped by the 2^{nd} source/drain pattern 123. Thus, a 1^{st} contact structure 114 for the 1^{st} source/drain pattern 113 can be formed at a lateral side of the 2^{nd} source/drain pattern 123 through this space S1 to contact at least a portion of the top surface of the 1^{st} source/drain pattern 113 because this space S1 is not occupied by the 2^{nd} source/drain pattern 123.

The 1^{st} contact structure 114 may be formed in an isolation structure 102 to contact a portion of the top surface of the 1^{st} source/drain pattern 113 not vertically overlapped by the 2^{nd} source/drain pattern 123 through the space S1. The 1^{st} contact structure 114 may be connected to a 1^{st} metal line M11 disposed at a level above a top surface of the 2^{nd} source/drain pattern 123 through a 1^{st} via structure V11. The 1^{st} contact structure 114 may be extended straight down from a top surface thereof to the top surface of the 1^{st} source/drain pattern 113 to contact the same. The 1^{st} contact structure 114 may be formed to connect the 1^{st} source/drain pattern 113 to a voltage source or another circuit element through the 1^{st} via structure V11 and the 1^{st} metal line M11.

The stacked FET device 10 may also include a 2^{nd} contact structure 124 adjacent to the 1^{st} contact structure 114 and formed on a top surface of the 2^{nd} source/drain pattern 123 to connect the 2^{nd} source/drain pattern 123 to the same voltage source to which the 1^{st} source/drain pattern 113 is connected, a different voltage source, the same circuit element to which the 1^{st} source/drain pattern 113 is connected, or a different circuit element through a 2^{nd} via structure V12 and a 2^{nd} metal line M12 disposed above the 2^{nd} source/drain pattern 123.

Otherwise, in a case where the 2^{nd} source/drain pattern 123 has an equal or greater width than the 1^{st} source/drain pattern 113, and thus, the 1^{st} source/drain pattern 123 is entirely overlapped by the 2^{nd} source/drain pattern 123 in the D3 direction, the stacked FET device 10 may need an additional area at a lateral side of the 2^{nd} source/drain pattern 123 having an increased width where a contact structure for the 1^{st} source/drain pattern 113 may be formed to connect the 1^{st} source/drain pattern 113 to the metal line M11. Further, this contact structure may have to be bent to contact the top surface or a side surface of the 1^{st} source/drain pattern 113.

Each of the contact structures 114 and 124 may be or may take a form of a via structure having a pillar shape like the via structures V11 and V12, not being limited thereto, and may be formed on a metal line, like the metal lines M11 and M12, extended in the D1 direction. Thus, the contact structures 114 and 124 may also be referred to as via structures. The via structures V11 and V12 may not be formed so that the contact structures 114 and 124 may be connected to the metal lines M11 and M12 without these via structures, according to one or more other embodiments. The stacked FET device 10 may also include a gate contact structure CB, which may take a form of via structure, connecting the gate structure 150 to a 3^{rd} metal line M13 to receive a gate input signal.

The contact structures 114, 124 and CB, the via structures V11 and V12, and the metal lines M11, M12 and M13 may have the same material composition or different metal compositions. For example, these structures may be formed of the same metal or metal compound or different metals or metal compounds, which may include, for example, tungsten (W), copper (Cu), aluminum (Al), molybdenum (Mo), ruthenium (Ru), etc., or a compound thereof. The isolation structure 102 may be formed of a low-k material such as silicon oxide (e.g., SiO₂).

In the meantime, at least on side surfaces of the contact structures 114, 124 and CB, the via structures V11 and V12, and the metal lines M11, M12 and M13 may be formed respective barrier metal layers preventing metal atoms of these metal structures from diffusing into the surrounding isolation structure 102. The barrier metal layers may be or include a metal or a metal nitride such as titanium (Ti), tantalum (Ta), titanium nitride (TiN), tantalum nitride (TaN), tungsten nitride (WN), nickel nitride (NiN), cobalt nitride (CoN), or platinum nitride (PtN), not being limited thereto. The barrier metal layer may be layered in holes or trenches formed in the isolation structure 102 before the contact structures 114, 124 and CB, the via structures V11 and V12, and the metal lines M11, M12 and M13 are formed therein. For example, the barrier metal layer may be formed in inner side surfaces of contact holes H1 and H2 wherein the contact structures 114 and 124 are formed or filled in, respectively. However, the barrier metal layer may not be formed in a hole or trench in which a metal such as ruthenium (Ru) is formed or filled in to form a contact structure, a via structure, or a metal line. This is because Ru exhibits a very limited diffusion of its metal atoms into the isolation structure.

A silicide layer such as cobalt silicide (CoSi₂), nickel silicide (NiSi₂), titanium silicide (TiSi₂), or tungsten silicide (WSi₂) may be formed on an interface of the 1^{st} contact structure 114 and the 1^{st} source/drain pattern 113 and on an interface of the 2^{nd} contact structure 124 and the 2^{nd} source/drain pattern 123 to reduce contact resistance between silicon (Si) of the source/drain patterns 113 and 123 and the metal or metal compound forming the contact structures 114 and 124.

Based on the above structural characteristics, the stacked FET device 10 including the different-width channel structures 112 and 122, the different-width source/drain patterns 113 and 123, and the 1^{st} contact structure 114 formed through the space S1 may be able to provide a reduced footprint for a semiconductor device including the stacked FET device 10 at least in the D2 direction. Because of the 2^{nd} channel structure 122 having a smaller width to forming the 2^{nd} FET 10B, the 2^{nd} channel structure 122 may have a greater number of nanosheet layers than the 1^{st} channel structure 112 forming the 1^{st} FET 10A so that the two FETs may have the same or substantially same effective channel width (W_{eff}). For example, the 2^{nd} channel structure 122 may have three nanosheet layers while the 1^{st} channel structure 112 have two nanosheet layers.

The different-width channel structures 112 and 122 with the different number of nanosheet layers and different-width source/drain pattern 113 and 123 may facilitate optimization of the stacked FET device 10 in terms of not only area gain for a high-density semiconductor device including the stacked FET device 10 but also enhanced device performance such as current speed, work load distribution, power efficiency, contact resistance, thermal control, structural stability, etc.

However, because the 1^{st} contact structure 114 connected to the 1^{st} source/drain pattern 113 is formed in the space S1 above the top surface of the 1^{st} source/drain pattern 113 which is proximate to the 2^{nd} source/drain pattern 123 as well as the 2^{nd} contact structure 124 connected to the 2^{nd} source/drain pattern 123, a first critical distance CD1 between the 1^{st} contact structure 114 and the 2^{nd} contact structure 124 and as a 2^{nd} critical distance CD2 between the 1^{st} contact structure 114 and the 2^{nd} source/drain pattern 123 may both become significantly smaller in the nanometer-scale device structure of the stacked FET device 10. Thus, there is an increased risk of short-circuit between the 1^{st} contact structure 114 and each of the 2^{nd} contact structure 124 and the 2^{nd} source/drain pattern 123.

The following embodiments address the foregoing risk of short-circuit in the stacked FET device 10.

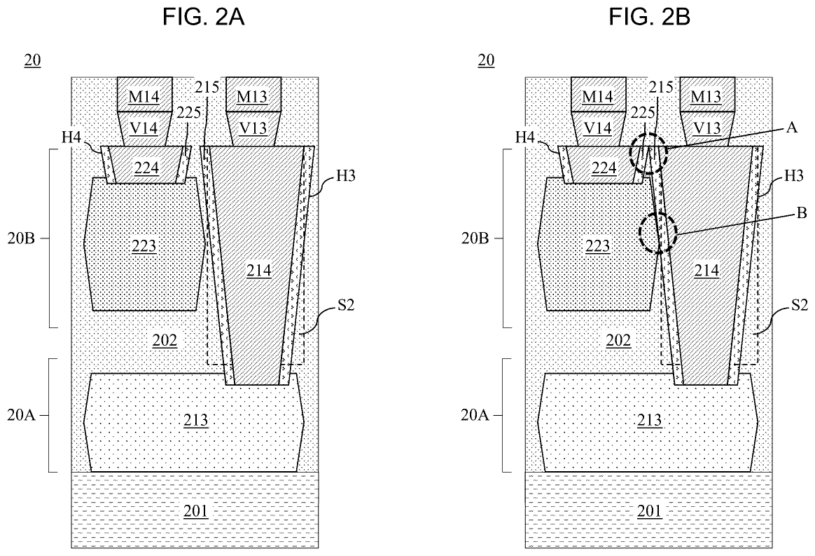

FIG. 2A illustrates a stacked FET device in which a 2^{nd} FET vertically stacked on a 1^{st} FET is formed to have a smaller width than the 1^{st} FET, and contact structures are surrounded by extra isolation layers, according to one or more embodiments, and FIG. 2B illustrates the stacked FET device of FIG. 2A in which contact structures surrounded by extra isolation layers are misaligned with source/drain patterns, according to one or more embodiments.

Referring to FIG. 2A, a stacked FET device 20 may be formed of the same structural elements forming the stacked FET device 10 shown in FIGS. 1A-1C. For example, the stacked FET device 20 may include a 1^{st} FET 20A formed on a base layer 201 and a 2^{nd} FET 20B stacked vertically above the 1^{st} FET 20A. Further, as in the stacked FET device 10 including the 1^{st} channel structure 112 and the 2^{nd} channel structure 122, a 1^{st} channel structure including a plurality of 1^{st} nanosheet layers in the 1^{st} FET 20A may have a greater width in the D2 direction than 2^{nd} channel structure including a plurality of 2^{nd} nanosheet layers in the 2^{nd} FET 20B. This is because the 1^{st} channel structure may be formed from a 1^{st} active pattern like the 1^{st} active pattern 110 shown in FIG. 1A having a greater width than a 2^{nd} active pattern, like the 2^{nd} active pattern 120 shown in FIG. 1A, from which the 2^{nd} channel structure is formed. Thus, a 1^{st} source/drain pattern 213 may also have a greater width in the D2 direction than the 2^{nd} source/drain pattern 223 and may provide a space S2 above a top surface thereof not vertically overlapped by the 1^{st} source/drain pattern 213. In addition, the 1^{st} channel structure and the 2^{nd} channel structure may each be surrounded by a corresponding gate structure similar to the gate structure 150 shown in FIG. 1A. Thus, duplicate descriptions thereof may be omitted herein

However, the stacked FET device 20 may differ from the stacked FET device 10 in that a 1^{st} contact structure 214 and a 2^{nd} contact structure 224 are laterally surrounded by a 1^{st} extra isolation layer 215 and a 2^{nd} extra isolation layer 225 in contact holes H3 and H4 formed in an isolation structure 202, respectively. These extra isolation layers 215 and 225 may be formed to provide additional secure isolation between the 1^{st} contact structure 214 and the 2^{nd} contact structure 224 and between the 1^{st} contact structure 214 and the 2^{nd} source/drain pattern 223.

The contact structures 214 and 224 may be formed of a metal such as tungsten (W), copper (Cu), aluminum (Al), molybdenum (Mo), ruthenium (Ru), etc., or a compound thereof, similar to the contact structures 114 and 224 of the stacked FET device 10.

The extra isolation layers 215 and 225 may each be formed of a material such as silicon nitride (e.g., Si₃N₄, etc.), SiC, SiCN, SiBCN, etc., not being limited thereto, which is different from a material such as silicon oxide (e.g., SiO₂, etc.) forming the isolation structure 202. These different materials may have etch selectivity against each other. Thus, an interface, a connection surface, or a junction may be formed between the isolation structure 202 and each of the extra isolation layers 215 and 225. However, the disclosure is not limited thereto. According to one or more other embodiments, an additional silicon oxide (e.g., SiO₂, etc.) may be formed in at least one of the contact holes H3 and H4 to form the 1^{st} extra isolation layer 215 and/or the 2^{nd} extra isolation layer 225, respectively. Even in this case, an interface, a connection surface, or a junction may be formed between the isolation structure 202 and each of the extra isolation layers 215 and 225 because the formation of the extra isolation layer 215 and/or 225 may be performed later than the formation of the isolation structure 202.

The 1^{st} extra isolation layer 215 may have a top surface and a bottom surface horizontally coplanar or aligned with a top surface and a bottom surface of the 1^{st} contact structure 214, respectively. The bottom surface of the 1^{st} extra isolation layer 215 along with the bottom surface of the 1^{st} contact structure 214 may contact the top surface of the 1^{st} source/drain pattern. The 1^{st} extra isolation layer 215 may be formed along or laterally surround an entire side surface of the 1^{st} contact structure 214. Likewise, the 2^{nd} extra isolation layer 225 may have a top surface and a bottom surface horizontally coplanar or aligned with a top surface and a bottom surface of the 2^{nd} contact structure 224, respectively. The bottom surface of the 2^{nd} extra isolation layer 225 along with the bottom surface of the 2^{nd} contact structure 224 may contact the top surface of the 2^{nd} source/drain pattern. The 2^{nd} extra isolation layer 225 may be formed along or laterally surround an entire side surface of the 2^{nd} contact structure 224.

However, the structure of the stacked FET device 20 providing secure isolation between the 1^{st} contact structure 214 and each of the 2^{nd} contact structure 224 and the 2^{nd} source/drain pattern 223 may not limited to that described above. In order to provide similar secure isolation, the 1^{st} extra isolation layer 215 may be formed only on a left side surface of the 1^{st} contact structure 214 facing the 2^{nd} contact structure 224 and the 2^{nd} source/drain pattern 223, according to one or more other embodiments. Further, in order to provide additional secure isolation only between the two contact structures 214 and 224, only the 1^{st} extra isolation layer 215 may be formed only on an upper portion of the left side surface of the 1^{st} contact structure 214 facing the 2^{nd} contact structure 224, or only the 2^{nd} extra isolation layer 225 may be formed on a right side surface of the 2^{nd} contact structure 224, according to one or more other embodiments.

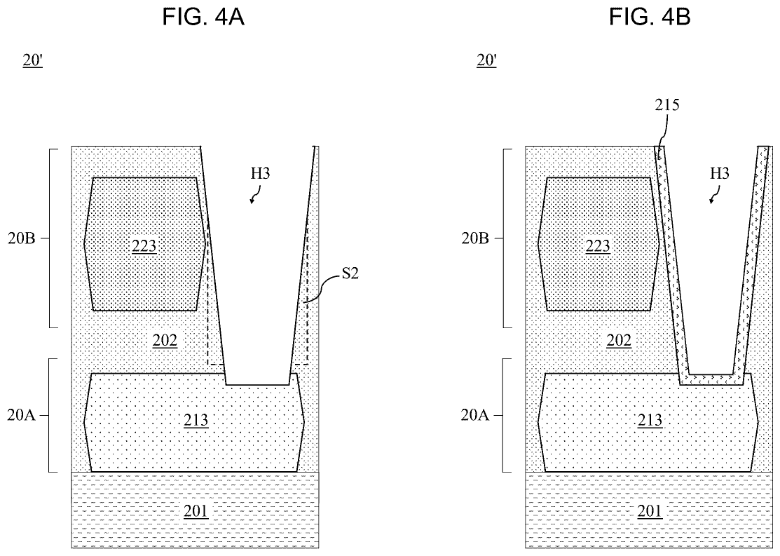

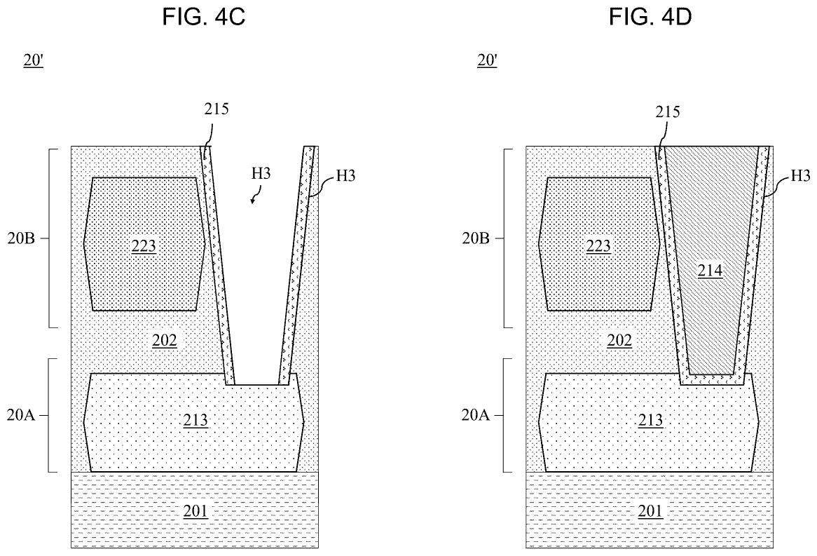

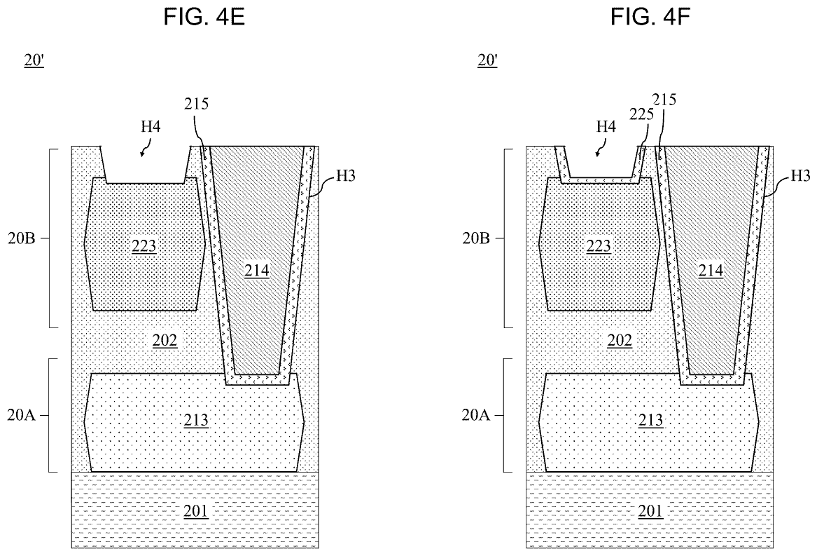

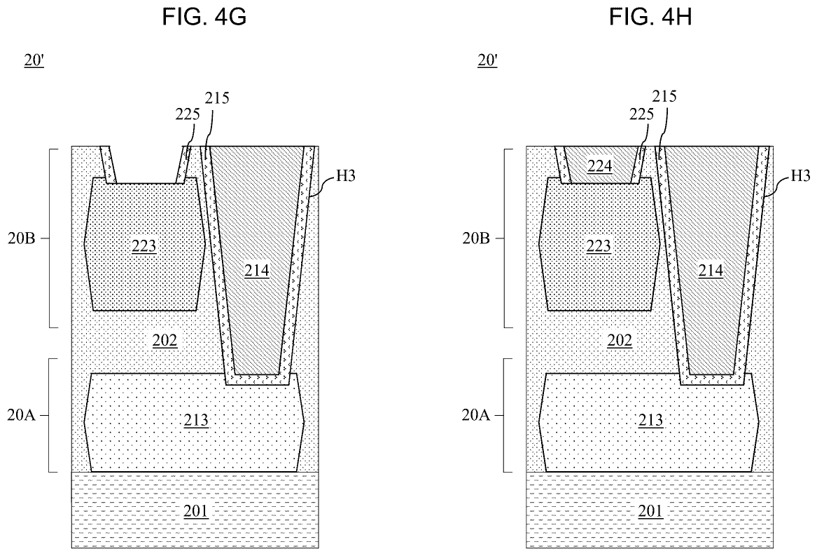

In the meantime, as will be described later in reference to FIGS. 4A-4H, the contact hole H3 with the 1^{st} extra isolation layer 215 and the 1^{st} contact structure 214 therein is formed earlier than the contract hole H4 with the 2^{nd} extra isolation layer 225 and the 2^{nd} contact structure 224 therein. Thus, even when patterning for the contact hole H4 is misaligned to be proximate to the contact hole H3, the contact hole H4 may be formed in a self-aligning manner based on the 1^{st} extra isolation layer 215 not to intrude or contact the 1^{st} contact structure 214 protected by the 1^{st} extra isolation layer 215 in the contact hole H3.

Accordingly, the 2^{nd} contact structure 224 formed in the contact hole H4 with the 2^{nd} extra isolation layer 225 may be provided with secure isolation from the 1^{st} contact structure 214. Similarly, when the contact hole H4 with the 2^{nd} extra isolation layer 225 and the 2^{nd} contact structure 224 therein is formed earlier than the contract hole H3 with the 1^{st} extra isolation layer 215 and the 1^{st} contact structure 214 therein, the 1^{st} contact structure 214 may be provided with secure isolation from the 2^{nd} contact structure 224 due to the 2^{nd} extra isolation layer 225 as well as the 1^{st} extra isolation layer 215.

FIG. 2B shows that the two contact holes H3 and H4 are formed in the isolation structure 202 to contact each other because of misaligned patterning on the isolation structure 202, and thus, no isolation structure 202 may exist at a connection surface or interface between the 1^{st} extra isolation layer 215 and the 2^{nd} extra isolation layer 225 as shown in area A indicated by a circle in FIG. 2B. However, due to the extra isolation layers 215 and 225, the contact holes H3 and H4 may be formed not to intrude or contact the 2^{nd} contact structure 224 and the 1^{st} contact structure 214, respectively. Further, in this case, the 1^{st} extra isolation layer 215 may isolate the 1^{st} contact structure 214 from the 2^{nd} source/drain pattern 223 even when the 1^{st} extra isolation layer 215 contacts the 2^{nd} source/drain pattern 223, and thus, no isolation structure 202 may exist at a contact surface or interface between the 1^{st} extra isolation layer 215 and the 2^{nd} source/drain pattern 223, as shown in area B indicated by a circle in FIG. 2B.

Thus, the stacked FET device 20 compared to the stacked FET device 10 of FIGS. 1A-1C may achieve an improved connection performance with a reduced short-circuit risk as well as manufacturing simplicity due to the extra isolation layers 215 and 225.

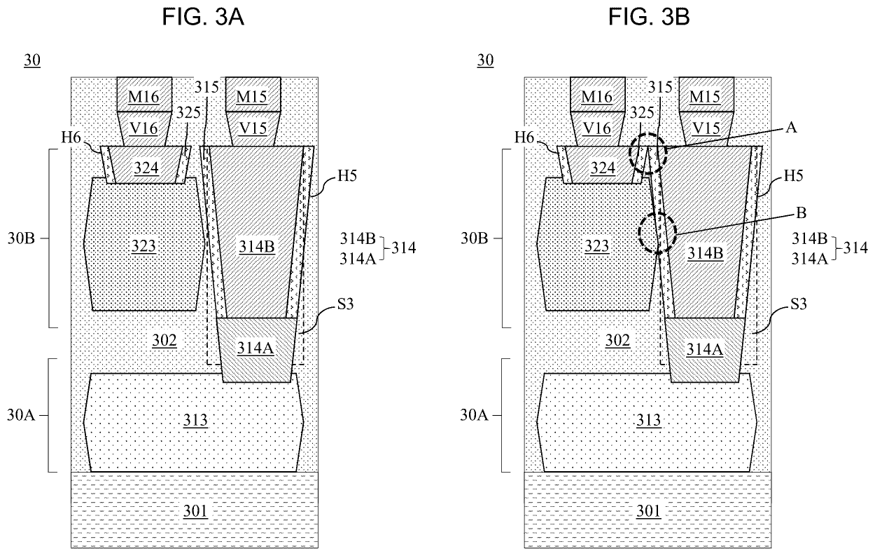

FIG. 3A illustrates a stacked FET device in which a 2^{nd} FET vertically stacked on a 1^{st} FET is formed to have a smaller width than the 1^{st} FET, contact structures are surrounded by extra isolation layers, and an extra metal structure is formed at a lower portion of one of the contact structures, according to one or more embodiments, and FIG. 3B illustrates the stacked FET device of FIG. 3A in which contact structures surrounded by extra isolation layers are misaligned with source/drain patterns, according to one or more embodiments.

Referring to FIG. 3A, a stacked FET device 30 may be formed of the same structural elements forming the stacked FET device 20 shown in FIG. 2A. For example, the stacked FET device 30 may include a 1^{st} FET 30A formed on a base layer 301 and a 2^{nd} FET 30B stacked vertically above the 1^{st} FET 30A. Further, as in the stacked FET device 10 including the 1^{st} channel structure 112 and the 2^{nd} channel structure 122, a 1^{st} channel structure including a plurality of 1^{st} nanosheet layers in the 1^{st} FET 30A may have a greater width in the D2 direction than 2^{nd} channel structure including a plurality of 2^{nd} nanosheet layers in the 2^{nd} FET 30B. This is because the 1^{st} channel structure may be formed from a 1^{st} active pattern like the 1^{st} active pattern 110 shown in FIG. 1A having a greater width than a 2^{nd} active pattern, like the 2^{nd} active pattern 120 shown in FIG. 1A, from which the 2^{nd} channel structure is formed. Thus, a 1^{st} source/drain pattern 313 may also have a greater width in the D2 direction than the 2^{nd} source/drain pattern 323 and may provide a space S3 above a top surface thereof not vertically overlapped by the 1^{st} source/drain pattern 313. In addition, the 1^{st} channel structure and the 2^{nd} channel structure may each be surrounded by a corresponding gate structure similar to the gate structure 150 shown in FIG. 1A. Thus, duplicate descriptions thereof may be omitted herein.

However, the stacked FET device 30 may differ from the stacked FET device 20 in that a 1^{st} contact structure 314 formed in a contact hole H5 in an isolation structure 302 includes a 1^{st} portion 314A and a 2^{nd} portion 314B vertically thereon. These two portions 314A and 314B of the 1^{st} contact structure 314 may be formed at different steps based on different materials as will be described later. Further, the 1^{st} portion 314A of the 1^{st} contact structure 314 may not be laterally surrounded by an extra isolation layer while the 2^{nd} portion 314B of the 1^{st} contact structure 314 is laterally surrounded by a 1^{st} extra isolation layer 315. In contrast, a 2^{nd} contact structure 324 and a 2^{nd} extra isolation layer 325 laterally surrounding the 2^{nd} contact structure 324 in a contact hole H6 formed in the isolation structure 302 may be the same as the 2^{nd} contact structure 224 and the 2^{nd} extra isolation layer 225 of the stacked FET device 20.

Referring back to FIG. 2A, the 1^{st} extra isolation layer 215 may not need to laterally surround a lower portion of the 1^{st} contact structure 214 because the 2^{nd} source/drain pattern 223 is not formed at a lateral side of the lower portion of the 1^{st} contact structure 214 and thus, there is no risk of a short-circuit between the 1^{st} contact structure 214 and the 2^{nd} source/drain pattern 223 in this region. Considering this aspect, the 1^{st} extra isolation layer 315 in the isolation structure 302 may be formed to laterally surround only an upper portion of the 1^{st} contact structure 314 at a lateral side of the 2^{nd} source/drain pattern 323 and the 2^{nd} contact structure 324, without being formed to laterally surround a lower portion of the 1^{st} contact structure 314, in the stacked FET device 30.

Thus, the 1^{st} extra isolation layer 315 may not be formed on an inner side surface of a lower portion of the contact hole H5 provided in the isolation structure 302 to form the 1^{st} contact structure 314 therein, and instead, a metal such as molybdenum (Mo) or a compound thereof providing a low contact resistance, a high thermal stability and a good stress reliability with respect to the 1^{st} source/drain pattern 313 may be filled to form the 1^{st} portion 314A of the 1^{st} contact structure 314 in the lower portion of the contact hole H5 to contact the 1^{st} source/drain pattern 313. As the 1^{st} extra isolation layer is not formed in a lower portion of the contact hole H5, a volume of the 1^{st} portion 314A of the 1^{st} contact structure 314 formed therein may be greater than that of a corresponding portion of the 1^{st} contact structure 214 formed in the contact hole H3 of the isolation structure 202 of the stacked FET device 20. Thus, a contact resistance between the 1^{st} contact structure 314 and the 1^{st} source/drain pattern 313 may be further reduced. In contrast, the 2^{nd} portion 314B of the 1^{st} contact structure 314 may be formed of a metal such as tungsten (W), copper (Cu), aluminum (Al), etc. or a compound thereof which provides ease of metal deposition. Thus, there may be formed an interface, a connection surface or junction between the two portions 314A and 314B of the 1^{st} contact structure 314. Here, a top surface of the 1^{st} portion 314A of the 1^{st} contact structure 314 may be at a level of or below a bottom surface of the 2^{nd} source/drain pattern 323.

However, although shortened, the 1^{st} extra isolation layer 315 may be formed at an entire side surface or only a portion of a side surface of the 2^{nd} portion 314B of the 1^{st} contact structure 314 to provide additional secure isolation between the 1^{st} contact structure 314 and each of the 2^{nd} contact structure 324 and the 2^{nd} source/drain pattern 323. For example, the 1^{st} extra isolation layer 315 may be formed only on a left side surface of the 2^{nd} portion 314B of the 1^{st} contact structure 314 facing the 2^{nd} contact structure 324 and the 2^{nd} source/drain pattern 323, according to one or more other embodiments. Further, in order to provide additional secure isolation only between the two contact structures 314 and 324, only the 1^{st} extra isolation layer 315 may be formed only on an upper portion of the left side surface of the 2^{nd} portion 314B of the 1^{st} contact structure 314 facing the 2^{nd} contact structure 324, or only the 2^{nd} extra isolation layer 325 may be formed on a right side surface of the 2^{nd} contact structure 324, according to one or more other embodiments.

The 2^{nd} contact structure 324 may be formed of a metal such as tungsten (W), copper (Cu), aluminum (Al), molybdenum (Mo), ruthenium (Ru), etc., or a compound thereof, similar to the 2^{nd} contact structure 224 of the stacked FET device 20.

FIG. 3B shows that the two contact holes H5 and H6 are formed in the isolation structure 302 to contact each other because of misaligned patterning on the isolation structure 302, and thus, no isolation structure 302 may exist at a connection surface or interface between the 1^{st} extra isolation layer 315 and the 2^{nd} extra isolation layer 325, as shown in area A indicated by a circle in FIG. 3B. However, due to the extra isolation layers 315 and 325, the contact holes H5 and H6 may be formed not to intrude or contact the 2^{nd} contact structure 324 and the 1^{st} contact structure 314, respectively. Further, in this case, the 1^{st} extra isolation layer 315 may isolate the 1^{st} contact structure 314 from the 2^{nd} source/drain pattern 323 even when the 1^{st} extra isolation layer 315 contacts the 2^{nd} source/drain pattern 323, and thus, no isolation structure 302 may exist at a contact surface or interface between the 1^{st} extra isolation layer 315 and the 2^{nd} source/drain pattern 323, as shown in area B indicated by a circle in FIG. 3B.

Herebelow, methods of manufacturing semiconductor devices corresponding to the stacked FET devices 20 and 30 respectively shown in FIGS. 2A and 3A are provided according to one or more embodiments.

FIGS. 4A-4H illustrate intermediate semiconductor devices obtained after respective steps of manufacturing a stacked FET device in which a 2^{nd} FET vertically stacked on a 1^{st} FET is formed to have a smaller width than the 1^{st} FET, and contact structures are surrounded by extra isolation layers, according to one or more embodiments.

As the stacked FET device manufactured through the respective steps as shown in FIGS. 4A-4H may be the same as or may correspond to the stacked FET device 20 shown in FIG. 2A, duplicate descriptions, including those about materials and structures, thereof may be omitted and the same reference numbers may be used in the descriptions herebelow.

Referring to FIG. 4A, an intermediate semiconductor device 20′ including a 1^{st} FET 20A and a 2^{nd} FET 20B stacked thereon is provided and a contact hole H3 may be formed in an isolation structure 202 surrounding a 1^{st} source/drain pattern 213 of the 1^{st} FET 20A and a 2^{nd} source/drain pattern 223 of the 2^{nd} FET 20B such that a top surface of the 1^{st} source/drain pattern 213 is exposed through the contact hole H3.

The intermediate semiconductor device 20′ may be formed such that the 2^{nd} source/drain pattern 223 of the 2^{nd} FET 20B has a smaller width than the 1^{st} source/drain pattern 213 of the 1^{st} FET 20A. Thus, a space S2 above a top surface of the 1^{st} source/drain pattern 213 which is not overlapped by the 2^{nd} source/drain pattern 223 is provided, and the contact hole H3 may be formed through this space S2 to expose the top surface of the 1^{st} source/drain pattern 213. The formation of the contact hole H3 in the isolation structure 202 may be performed through, for example, dry etching or wet etching.

Referring to FIG. 4B, a 1^{st} extra isolation layer 215 may be formed on inner surfaces of the contact hole H3.

The 1^{st} extra isolation layer 215 may be formed along an inner surface of the contact hole H3 through, for example, atomic layer deposition (ALD) of a material such as silicon nitride (e.g., Si₃N₄, etc.), SiC, SiCN, SiBCN, etc., not being limited thereto, which is different from a material such as silicon oxide (e.g., SiO₂, etc.) forming the isolation structure 202.

The 1^{st} extra isolation layer 215 may be formed on an entire inner surface of the contact hole H3. However, according to one or more other embodiments, the 1^{st} extra isolation layer 215 may be formed only on a left side surface facing the 2^{nd} source/drain pattern 223 and a portion thereabove where a 2^{nd} contact structure 224 for the 2^{nd} source/drain pattern 223 is to be formed.

Referring to FIG. 4C, a bottom portion of the 1^{st} extra isolation layer 215 may be removed to expose the 1^{st} source/drain pattern 213.

When the 1^{st} extra isolation layer 215 is formed an entire inner surface of the contact hole H3 in the previous step, a bottom portion of the 1^{st} extra isolation layer 215 may be removed or opened through, for example, dry etching or wet etching to expose the 1^{st} source/drain pattern 213 therethrough. The exposed portion of the 1^{st} source/drain pattern 213 may be a top surface thereof.

Referring to FIG. 4D, a 1^{st} contact structure 214 may be formed by filling a metal or metal compound in the contact hole H3 with the 1^{st} extra isolation layer 215 thereon.

The 1^{st} contact structure 214 may be formed by depositing a metal such as tungsten (W), copper (Cu), aluminum (Al), molybdenum (Mo), ruthenium (Ru), etc., or a compound thereof in the contact hole H3 on which the 1^{st} extra isolation layer 215 is layered through, for example, chemical vapor deposition (CVD), plasma enhanced CVD (PECVD), physical vapor deposition (PVD), atomic layer deposition (ALD), etc. The deposition of the metal or metal compound in the contact hole H3 may be followed by planarization on top through, for example, chemical-mechanical polishing (CMP).

Referring to FIG. 4E, a contact hole H4 exposing the 2^{nd} source/drain pattern 223 may be formed in the isolation structure 202.

The contact hole H4 may be formed through, for example, dry etching or wet etching to expose a top surface of the 2^{nd} source/drain pattern 223. At this time, however, patterning misalignment may occur, and thus, the position of the contact hole H4 may move to the right to contact the contact hole H3. However, this contact hole H4 may still be formed not to intrude or contact the 1^{st} contact structure 214 surrounded by the 1^{st} extra isolation layer 215 in the contact hole H3 as described in reference to FIG. 2B. This is because an etchant such as hydrofluoric acid (HF) or buffered oxide etchant (BOE) may selectively etch silicon oxide (SiO₂) forming the isolation structure 202 against a material a material such as silicon nitride (e.g., Si₃N₄, etc.), SiC, SiCN, SiBCN, etc. forming the 1^{st} extra isolation layer 215.

Referring to FIG. 4F, a 2^{nd} extra isolation layer 225 may be formed on inner surfaces of the contact hole H4.

The 2^{nd} extra isolation layer 225 may be formed along an inner surface of the contact hole H4 through, for example, atomic layer deposition (ALD) of the same material forming the 1^{st} extra isolation layer 215.

The 1^{st} extra isolation layer 225 may be formed on an entire inner surface of the contact hole H4. However, according to one or more other embodiments, the 2^{nd} extra isolation layer 225 may be formed only on a right side surface facing the 1^{st} contact structure 214.

Referring to FIG. 4G, a bottom portion of the 2^{nd} extra isolation layer 225 may be removed to expose the 2^{nd} source/drain pattern 223.

When the 2^{nd} extra isolation layer 225 is formed an entire inner surface of the contact hole H4 in the previous step, a bottom portion of the 2^{nd} extra isolation layer 225 may be removed or opened through, for example, dry etching or wet etching to expose the 2^{nd} source/drain pattern 223 therethrough. The exposed portion of the 2^{nd} source/drain pattern 223 may be a top surface thereof.

Referring to FIG. 4H, a 2^{nd} contact structure 224 may be formed by filling a metal or metal compound in the contact hole H4 with the 2^{nd} extra isolation layer 225 thereon.

The 2^{nd} contact structure 224 may be formed by depositing the same metal or metal compound forming the 1^{st} contact structure 214 using the same deposition method used in the formation of the 1^{st} contact structure 214. The deposition of the metal or metal compound in the contact hole H4 may be followed by planarization on top through, for example, CMP.

Further, via structures and metal lines such as the via structures V13 and V14 and the metal lines M13 and M14 may be formed to contact the 1^{st} contact structure 214 and the 2^{nd} contact structure 224, respectively, as shown in FIG. 2A.

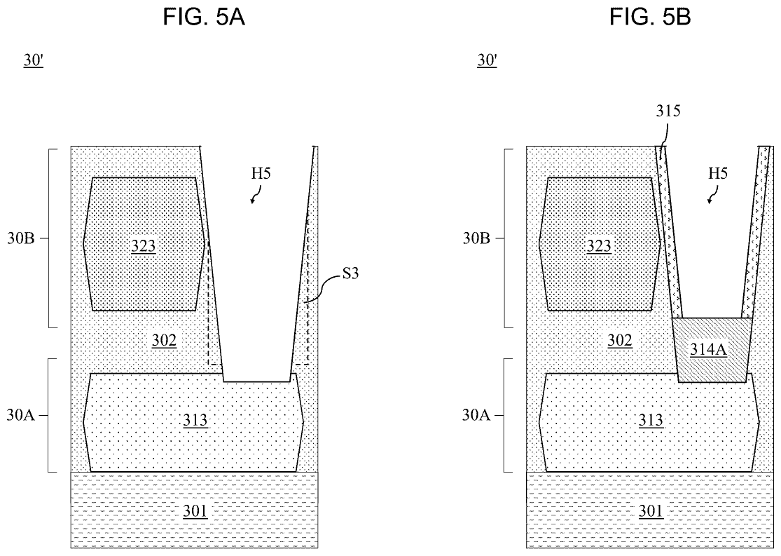

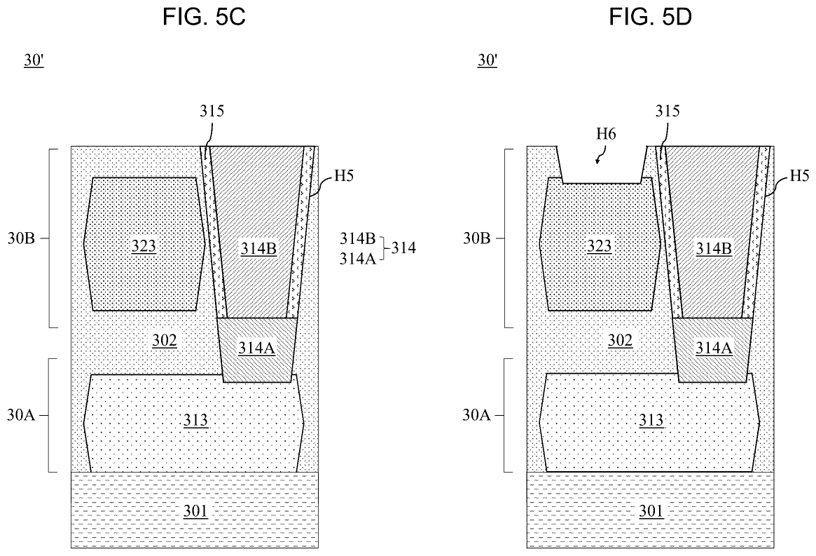

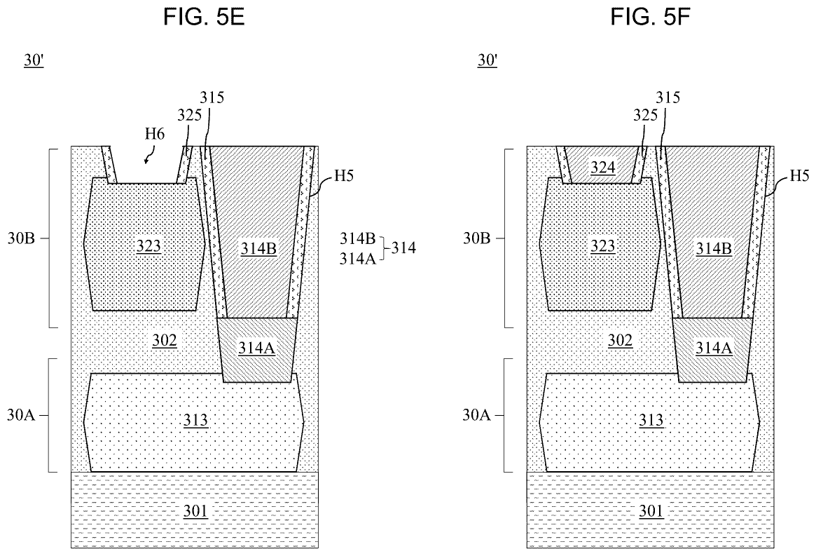

FIGS. 5A-5F illustrate intermediate semiconductor devices obtained after respective steps of manufacturing a stacked FET device in which a 2^{nd} FET vertically stacked on a 1^{st} FET is formed to have a smaller width than the 1^{st} FET, contact structures are surrounded by extra isolation layers, and an extra metal structure is formed at a lower portion of one of the contact structures, according to one or more embodiments.

As the stacked FET device manufactured through the respective steps as shown in FIGS. 5A-5F may be the same as or may correspond to the stacked FET device 30 shown in FIG. 3A, duplicate descriptions, including those about materials and structures, thereof may be omitted and the same reference numbers may be used in the descriptions herebelow.

Referring to FIG. 5A, an intermediate semiconductor device 30′ including a 1^{st} FET 30A and a 2^{nd} FET 30B thereon is provided and a contact hole 53 may be formed in an isolation structure 302 surrounding a 1^{st} source/drain pattern 313 of the 1^{st} FET 30A and a 2^{nd} source/drain pattern 323 of the 2^{nd} FET 30B such that a top surface of the 1^{st} source/drain pattern 313 is exposed through the contact hole H5.

The intermediate semiconductor device 30′ may be formed such that the 2^{nd} source/drain pattern 323 of the 2^{nd} FET 30B has a smaller width than the 1^{st} source/drain pattern 313 of the 1^{st} FET 30A. Thus, a space S3 above a top surface of the 1^{st} source/drain pattern 313 which is not overlapped by the 2^{nd} source/drain pattern 323 is provided, and the contact hole H3 may be formed through this space S3 to expose the top surface of the 1^{st} source/drain pattern 313. The formation of the contact hole H5 in the isolation structure 302 may be performed through, for example, dry etching or wet etching.

Referring to FIG. 5B, a lower portion of the contact hole H5 may be filled in with a metal or metal compound to form a 1^{st} portion 314A of a 1^{st} contact structure 314 for the 1^{st} source/drain pattern 313, and a 1^{st} extra isolation layer 315 may be formed on inner surfaces of the contact hole H3 above the 1^{st} portion 314A.

Unlike in the contact hole H3 formed in the isolation structure 202 of the stacked FET device 20 of FIG. 4A, the 1^{st} extra isolation layer 315 is not formed in a lower portion of the 1^{st} contact hole H5. This is because the 2^{nd} source/drain pattern 323 to be isolated from the 1^{st} contact structure 314 for the 1^{st} source/drain pattern 313 is not disposed at a lateral side of the lower portion of the 1^{st} contact hole in which a lower portion of the 1^{st} contact structure 314 is to be formed. Thus, instead of forming the 1^{st} extra isolation layer 315 in the lower portion of the contact hole H5, an extra metal or metal compound may fill in the lower portion of the contact hole H5 to form the 1^{st} portion 314A of the 1^{st} contact structure 314 to increase a metal volume of the 1^{st} contact structure 314 to he formed therein such that a top surface of the 1^{st} portion 314A is formed below a bottom surface of the 2^{nd} source/drain pattern 323.

The 1^{st} portion 314A of the contact structure for the 1^{st} source/drain pattern 313 may be formed by depositing a metal such as molybdenum (Mo) or a compound thereof in the lower portion of the contact hole H5 such that a top surface of the 1^{st} portion 314A is disposed below a bottom surface of the 2^{nd} source/drain pattern 323. The deposition may be performed through, for example, CVD, PVD, PECVD, etc., or a combination thereof. Molybdenum (Mo) or a compound thereof is formed as the 1^{st} portion 314A as this metal provides a low contact resistance, a high thermal stability and a good stress reliability with respect to the 1^{st} source/drain pattern 313.

Above the 1^{st} portion 314A may be formed the 1^{st} extra isolation layer 315 along an inner surface of the contact hole H5 through, for example, atomic layer deposition (ALD) of a material such as silicon nitride (e.g., Si₃N₄, etc.), SiC, SiCN, SiBCN, etc., not being limited thereto, which is different from a material such as silicon oxide (e.g., SiO₂, etc.) forming the isolation structure 302.

The 1^{st} extra isolation layer 315 may be formed on an entire inner surface of the contact hole H5. However, according to one or more other embodiments, the 1^{st} extra isolation layer 315 may be formed only on a left side surface facing the 2^{nd} source/drain pattern 323 and a portion thereabove where a 2^{nd} contact structure 324 for the 2^{nd} source/drain pattern 323 is to be formed. Further, a bottom surface of the 1^{st} extra isolation layer 315 contacting the 1^{st} portion 314A of the 1^{st} contact structure 314 may be removed or open through, for example, dry etching or wet etching to expose the 1^{st} portion 314A through the contact hole H5.

As described earlier in reference to FIG. 3A, the 1^{st} extra isolation layer 315 may not be formed on an inner surface of the lower portion of the contact hole H5 because the 2^{nd} source/drain pattern 323, which is an additional isolation target of the contact structure for the 1^{st} source/drain pattern 313, is not formed at a lateral side of the lower portion of the contact hole H5.

Referring to FIG. 5C, a 2^{nd} portion 314B of the 1^{st} contact structure 314 for the 1^{st} source/drain pattern 313 may be formed on the 1^{st} portion 314A by filling a metal or metal compound in the contact hole H5 with the 1^{st} extra isolation layer 315 thereon, thereby completing the 1^{st} contact structure 314 on the 1^{st} source/drain pattern 313.

The 2^{nd} portion 314B of the 1^{st} contact structure 314 may be formed by depositing a metal such as tungsten (W), copper (Cu), aluminum (Al), etc. or a compound thereof which provides ease of deposition in the contact hole H3 through, for example, CVD, PECVD, PVD, ALD, etc., or a combination thereof. The deposition of the metal or metal compound in the contact hole H5 may be followed by planarization on top through, for example, CMP.

Referring to FIG. 5D, a contact hole H6 exposing the 2^{nd} source/drain pattern 323 may be formed in the isolation structure 202.

The contact hole H6 may be formed through, for example, dry etching or wet etching to expose a top surface of the 2^{nd} source/drain pattern 323. At this time, however, patterning misalignment may occur, and thus, the position of the contact hole H6 may move to the right to contact the contact hole H5. However, this contact hole H6 may still be formed not to intrude or contact the 1^{st} contact structure 314 surrounded by the 1^{st} extra isolation layer 315 in the contact hole H5 as described in reference to FIG. 3B. This is because an etchant such as hydrofluoric acid (HF) or buffered oxide etchant (BOE) may selectively etch silicon oxide (SiO₂) forming the isolation structure 302 against a material a material such as silicon nitride (e.g., Si₃N₄, etc.), SiC, SiCN, SiBCN, etc. forming the 1^{st} extra isolation layer 315.

Referring to FIG. 5E, a 2^{nd} extra isolation layer 325 may be formed on inner surfaces of the contact hole H6 and a bottom surface of the 2^{nd} extra isolation layer 325 may be removed to expose the 2^{nd} source/drain pattern 323 through the contact hole H6.

The 2^{nd} extra isolation layer 325 may be formed along an inner surface of the contact hole H6 through, for example, atomic layer deposition (ALD) of the same material forming the 1^{st} extra isolation layer 315. The 1^{st} extra isolation layer 325 may be formed on an entire inner surface of the contact hole H6. However, according to one or more other embodiments, the 2^{nd} extra isolation layer 325 may be formed only on a right side surface facing the 1^{st} contact structure 314.

When the 2^{nd} extra isolation layer 325 is formed an entire inner surface of the contact hole H6, a bottom portion of the 2^{nd} extra isolation layer 325 may be removed or opened through, for example, dry etching or wet etching to expose the 2^{nd} source/drain pattern 323 therethrough. The exposed portion of the 2^{nd} source/drain pattern 323 may be a top surface thereof.

Referring to FIG. 5F, a 2^{nd} contact structure 324 may be formed by forming a metal or metal compound in the contact hole H6 with the 2^{nd} extra isolation layer 325 thereon.

The 2^{nd} contact structure 324 may be formed by depositing the same metal or metal compound forming the 2^{nd} contact structure 224 of the stacked FET device 20 using the same deposition method used in the formation of the 2^{nd} contact structure 224.

Further, via structures and metal lines such as the via structures V15 and V16 and the metal lines M15 and M16 may be formed to contact the 1^{st} contact structure 314 and the 2^{nd} contact structure 324, respectively, as shown in FIG. 3A.

It is understood here that although particular materials, etchants and methods are described as being used to form various structural elements of the stacked FET devices 10, 20 and 30 in the above embodiments, the disclosure is not limited thereto, and thus, other materials, etchants and methods may also be used to form the same structural elements to serve the same or similar purposes, according to one or more other embodiments.

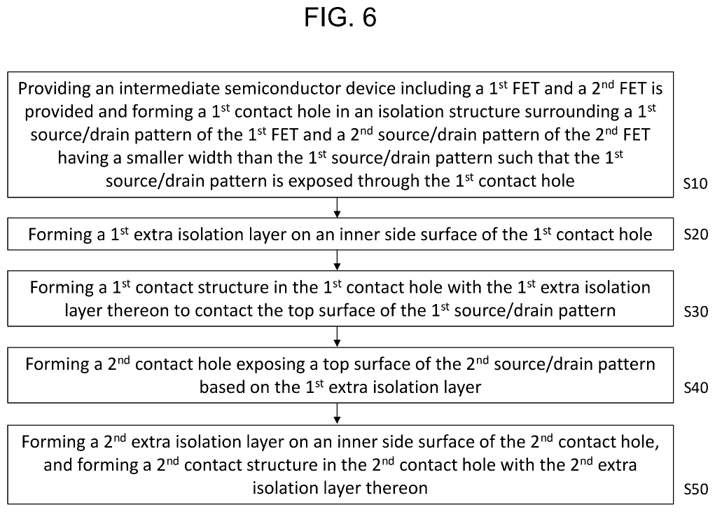

FIG. 6 is a flowchart of manufacturing a stacked FET device in which a 2^{nd} FET vertically stacked on a 1^{st} FET is formed to have a smaller width than the 1^{st} FET, and contact structures are surrounded by extra isolation layers, according to one or more embodiments.

The stacked FET device formed through the flowchart of FIG. 6 may be the same or similar to the stacked FET device 20 manufactured in reference to FIGS. 4A-4H.

In step S10, an intermediate semiconductor device including a 1^{st} FET and a 2^{nd} FET stacked thereon is provided and a 1^{st} contact hole may be formed in an isolation structure surrounding a 1^{st} source/drain pattern of the 1^{st} FET and a 2^{nd} source/drain pattern of the 2^{nd} FET having a smaller width than the 1^{st} source/drain pattern such that a top surface of the 1^{st} source/drain pattern is exposed through the 1^{st} contact hole. The 1^{st} contact hole may be formed though a space above a top surface of the 1^{st} source/drain pattern which is not vertically overlapped by the 2^{nd} source/drain pattern.

In step S20, a 1^{st} extra isolation layer may be formed on an inner side surface of the 1^{st} contact hole including at least a portion of the side surface facing the 2^{nd} source/drain pattern. The 1^{st} extra isolation layer may be formed of a dielectric material (e.g., silicon nitride) which is different from a material (e.g., silicon oxide) forming the isolation structure in terms of etch selectivity.

In step S30, a 1^{st} contact structure may be formed in the 1^{st} contact hole with the 1^{st} extra isolation layer thereon to contact the top surface of the 1^{st} source/drain pattern. A metal or metal compound to form the 1^{st} contact structure may be tungsten (W), copper (Cu), aluminum (Al), molybdenum (Mo), ruthenium (Ru), etc., or a compound thereof.

In step S40, a 2^{nd} contact hole exposing a top surface of the 2^{nd} source/drain pattern may be formed based on the 1^{st} extra isolation layer. As the 1^{st} extra isolation layer may be formed of the dielectric material having etch selectivity against the material forming the isolation structure, the 2^{nd} contact hole may be formed not to intrude or contact the 1^{st} contact structure surrounded by the 1^{st} extra isolation layer in the 1^{st} contact hole.

In step S50, a 2^{nd} extra isolation layer may be formed on an inner side surface of the 2^{nd} contact hole, and a 2^{nd} contact structure may be formed in the 2^{nd} contact hole with the 2^{nd} extra isolation layer thereon. The 2^{nd} extra isolation layer and the 2^{nd} contact structure may be formed of the same material forming the 1^{st} extra isolation layer and the 1^{st} contact structure, respectively.

Thus, the 1^{st} extra isolation layer and the 2^{nd} extra isolation layer may provide additional secure isolation between the 1^{st} contact structure and each of the 2^{nd} contact structure and the 2^{nd} source/drain pattern in a stacked FET device.

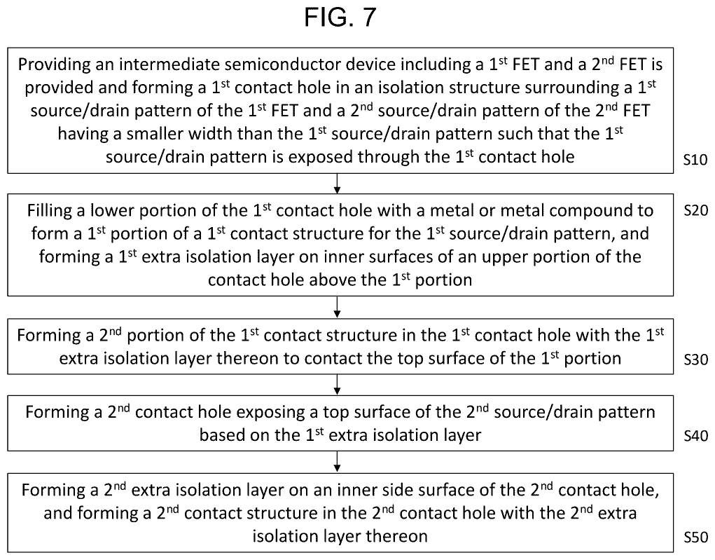

FIG. 7 is a flowchart of manufacturing a stacked FET device in which a 2^{nd} FET vertically stacked on a 1^{st} FET is formed to have a smaller width than the 1^{st} FET, contact structures are surrounded by extra isolation layers, and an extra metal structure is formed at a lower portion of one of the contact structures, according to one or more embodiments.

The stacked FET device formed through the flowchart of FIG. 7 may be the same or similar to the stacked FET device 30 manufactured in reference to FIGS. 5A-5F.

In step S10, an intermediate semiconductor device including a 1^{st} FET and a 2^{nd} FET stacked thereon is provided, and a 1^{st} contact hole may be formed in an isolation structure surrounding a 1^{st} source/drain pattern of the 1^{st} FET and a 2^{nd} source/drain pattern of the 2^{nd} FET having a smaller width than the 1^{st} source/drain pattern such that a top surface of the 1^{st} source/drain pattern is exposed through the 1^{st} contact hole. The 1^{st} contact hole may be formed though a space above a top surface of the 1^{st} source/drain pattern which is not vertically overlapped by the 2^{nd} source/drain pattern.

In step S20, a lower portion of the 1^{st} contact hole may be filled in with a metal or metal compound to form a 1^{st} portion of a 1^{st} contact structure for the 1^{st} source/drain pattern, and a 1^{st} extra isolation layer may be formed on an inner side surface of an upper portion of the contact hole above the 1^{st} portion.

The 1^{st} extra isolation layer is not formed in a lower portion of the 1^{st} contact hole considering that the 2^{nd} source/drain pattern to be isolated from the 1^{st} contact structure for the 1^{st} source/drain pattern is not disposed at a lateral side of the lower portion of the 1^{st} contact hole. Thus, instead of forming the 1^{st} extra isolation layer, the 1^{st} portion of the 1^{st} contact structure for the 1^{st} source/drain pattern may fill the lower portion of the 1^{st} contact hole such that a top surface thereof is formed below a bottom surface of the 2^{nd} source/drain pattern. The 1^{st} portion of the 1^{st} contact structure may be formed of a metal such as molybdenum (Mo) or a compound thereof providing a low contact resistance, a high thermal stability and a good stress reliability with respect to the 1^{st} source/drain pattern.

Above the 1^{st} portion of the 1^{st} contact structure in the 1^{st} contact hole may be formed the 1^{st} extra isolation layer of a dielectric material (e.g., silicon nitride) which is different from a material (e.g., silicon oxide) forming the isolation structure in terms of etch selectivity.

In step S30, a 2^{nd} portion of the 1^{st} contact structure may be formed in the 1^{st} contact hole with the 1^{st} extra isolation layer thereon to contact the top surface of the 1^{st} portion. The 2^{nd} portion of the 1^{st} contact structure may be formed of a metal such as tungsten (W), copper (Cu), aluminum (Al), etc. or a compound thereof which provides ease of deposition in the 1^{st} contact hole.

In step S40, a 2^{nd} contact hole exposing a top surface of the 2^{nd} source/drain pattern may be formed based on the 1^{st} extra isolation layer. As the 1^{st} extra isolation layer may be formed of the dielectric material having etch selectivity against the material forming the isolation structure, the 2^{nd} contact hole may be formed not to intrude or contact the 1^{st} contact structure surrounded by the 1^{st} extra isolation layer in the 1^{st} contact hole.

In step S50, a 2^{nd} extra isolation layer may be formed on an inner side surface of the 2^{nd} contact hole, and a 2^{nd} contact structure may be formed in the 2^{nd} contact hole with the 2^{nd} extra isolation layer thereon. The 2^{nd} extra isolation layer may be formed of the same dielectric material forming the 1^{st} extra isolation layer, and the 2^{nd} contact structure may be formed of a metal such as tungsten (W), copper (Cu), aluminum (Al), molybdenum (Mo), ruthenium (Ru), etc., or a compound thereof.

Thus, the 1^{st} extra isolation layer and the 2^{nd} extra isolation layer may provide additional secure isolation between the 1^{st} contact structure and each of the 2^{nd} contact structure and the 2^{nd} source/drain pattern in a stacked FET device, and the 1^{st} portion of the 1^{st} contact structure formed in the lower portion of the 1^{st} contact hole may reduce a contact resistance of the 1^{st} contact structure with respect to the 1^{st} source/drain pattern.

In the embodiments described above, a nanosheet transistor is represented to form each of the 1^{st} FET formed at the 1^{st} level and the 2^{nd} FET formed at the 2^{nd} level in the stacked FET devices 10, 20 and 30 shown in FIGS. 1A-1C, 2A-2B and 3A-3B. However, the disclosure is not limited thereto. According to one or more other embodiments, each of the stacked FET devices 10, 20 and 30 may be formed of different types of FET (e.g., FinFET, forksheet transistor, etc.) as the 1^{st} FET or the 2^{nd} FET.

In the above embodiments, the contact structure with an extra isolation layer thereon is formed on a source/drain pattern of a stacked FET device. However, the disclosure is not limited thereto. The contact structure with an extra isolation layer may also be formed on a different structural element, such as a gate structure, of various types of semiconductor device, according to one or more other embodiments. Further, the contact structure with an extra isolation layer may be used as a via structure connecting metal lines, according to one or more other embodiments.

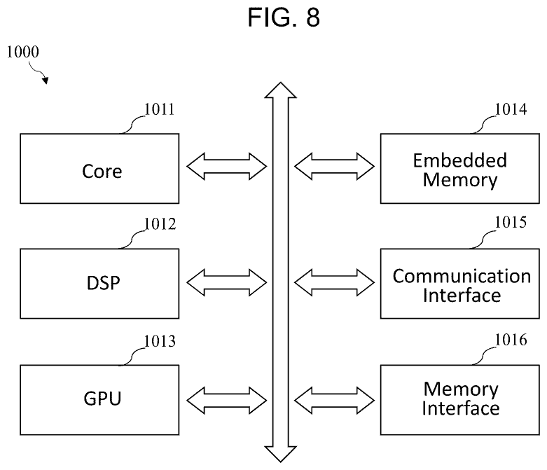

FIG. 8 is a schematic block diagram illustrating an electronic device including one or more stacked FET devices shown in FIGS. 1A-1C, 2A-2B and 3A-3B, according to one or more embodiments.

Referring to FIG. 8, an SoC 1000 may be an integrated circuit in which components of a computing system or other electronic systems are integrated. As an example of the SoC 1000, an application processor (AP) may include at least one processor and components for various functions. The SoC 1000 may include a core 1011 (e.g., a processor), a digital signal processor (DSP) 1012, a graphic processing unit (GPU) 1013, an embedded memory 1014, a communication interface 1015, and a memory interface 1016. The components of the SoC 1000 may communicate with each other through a bus 1007.

The core 1011 may process instructions and control operations of the components included in the SoC 1000. For example, the core 1011 may process a series of instructions to run an operating system and execute applications on the operating system. The DSP 1012 may generate useful data by processing digital signals (e.g., a digital signal provided from the communication interface 1015). The GPU 1013 may generate data for an image output by a display device from image data provided from the embedded memory 1014 or the memory interface 1016, or may encode the image data.

The embedded memory 1014 may store data necessary for the core 1011, the DSP 1012, and the GPU 1013 to operate. The communication interface 1015 may provide an interface for a communication network or one-to-one communication. The memory interface 1016 may provide an interface for an external memory of the SoC 1000, such as a dynamic random access memory (DRAM), a flash memory, etc.

At least one of the core 1011, the DSP 1012, the GPU 1013, and/or the embedded memory 1014 may include one or more of the stacked FET devices shown in FIGS. 1A-1C, 2A-2B and 3A-3B, according to one or more embodiments.

The foregoing is illustrative of example embodiments and is not to be construed as limiting the disclosure. Although a few example embodiments have been described, those skilled in the art will readily appreciate that many modifications are possible in the above embodiments without materially departing from the disclosure.

1. A semiconductor device comprising:
an isolation structure;
a 1^{st} contact structure in the isolation structure;
a 2^{nd} contact structure adjacent to and at a lateral side of the 1^{st} contact structure, in the isolation structure;
wherein at least one of the 1^{st} contact structure and the 2^{nd} contact structure has an extra isolation layer on a side surface thereof facing the other of the 1^{st} contact structure and the 2^{nd} contact structure.

2. The semiconductor device of claim 1, wherein each of the 1^{st} contact structure and the 2^{nd} contact structure has the extra isolation layer on the side surface thereof facing the other of the 1^{st} contact structure and the 2^{nd} contact structure.

3. The semiconductor device of claim 1, wherein the 1^{st} contact structure and the 2^{nd} contact structure are connected laterally with the extra isolation layer therebetween without the isolation structure therebetween.

4. The semiconductor device of claim 1, further comprising:
a 1^{st} source/drain pattern on which the 1^{st} contact structure is formed; and
a 2^{nd} source/drain pattern on which the 2^{nd} contact structure is formed;

5. (canceled)

6. (canceled)

7. The semiconductor device of claim 4, wherein the 1^{st} source/drain pattern is partially overlapped by the 2^{nd} source/drain pattern in a vertical direction, and
wherein the 1^{st} contact structure is connected to a top surface of the 1^{st} source/drain pattern through a space vertically above the top surface of the 1^{st} source/drain pattern which is not occupied by the 2^{nd} source/drain pattern.

8. The semiconductor device of claim 7, wherein the 1^{st} contact structure has the extra isolation layer on the side surface facing the 2^{nd} contact structure,
wherein the extra isolation layer is extended along the side surface thereof to be disposed at a lateral side of the 2^{nd} source/drain pattern.

9. The semiconductor device of claim 4, wherein the 1^{st} contact structure has the extra isolation layer on a side surface thereof facing the 2^{nd} contact structure, and
wherein the 1^{st} contact structure comprises:
a 1^{st} portion on a top surface of the 1^{st} source/drain pattern; and
a 2^{nd} portion vertically above the 1^{st} portion, and
wherein the extra isolation layer is not formed on a side surface of the 1^{st} portion.

10. The semiconductor device of claim 9, wherein the 1^{st} portion and the 2^{nd} portion have different material compositions.

11. (canceled)

12. (canceled)

13. The semiconductor device of claim 4, wherein the 1^{st} contact structure has the extra isolation layer on a side surface thereof facing the 2^{nd} contact structure and the 2^{nd} source/drain pattern, and
wherein the extra isolation layer contacts the 2^{nd} source/drain pattern without the isolation structure therebetween.

14. The semiconductor device of claim 1, wherein the at least one of the 1^{st} contact structure and the 2^{nd} contact structure is laterally surrounded by the extra isolation layer.

15. The semiconductor device of claim 1, wherein the isolation structure and the extra isolation layer have different material compositions.

16. The semiconductor device of claim 1, wherein an interface, a connection surface or a junction is formed between the isolation structure and the extra isolation layer.

17. A semiconductor device comprising:
an isolation structure; and
a contact structure with an extra isolation layer on a side surface thereof, in the isolation structure.

18. The semiconductor device of claim 17, wherein the contact structure comprises:
a 1^{st} portion; and
a 2^{nd} portion vertically above the 1^{st} portion,
wherein the extra isolation layer is not formed on a side surface of the 1^{st} portion.

19. The semiconductor device of claim 18, wherein the 1^{st} portion and the 2^{nd} portion have different material compositions.

20. (canceled)

21. The semiconductor device of claim 18, wherein an interface, a connection surface, or a junction is formed between the 1^{st} portion and the 2^{nd} portion.

22. A method of manufacturing a semiconductor device, the method comprising:
forming an isolation structure;
forming a 1^{st} contact structure in the isolation structure; and
forming a 2^{nd} contact structure adjacent to and at a lateral side of the 1^{st} contact structure, in the isolation structure,
wherein at least one of the 1^{st} contact structure and the 2^{nd} contact structure is formed to have an extra isolation layer on a side surface thereof facing the other of the 1^{st} contact structure and the 2^{nd} contact structure.

23. The method of claim 22, wherein one of the 1^{st} contact structure and the 2^{nd} contact structure is formed in a contact hole which is formed based on the extra isolation layer formed on the side surface of the other of the 1^{st} contact structure and the 2^{nd} contact structure.

24. (canceled)

25. The method of claim 22, further comprising:
forming a 1^{st} source/drain pattern on which the 1^{st} contact structure is formed; and
forming a 2^{nd} source/drain pattern on which the 2^{nd} contact structure is formed,
wherein the 1^{st} source/drain pattern is formed vertically below the 2^{nd} source/drain pattern, and the 1^{st} source/drain pattern has a greater width than the 2^{nd} source/drain pattern, and
wherein the 1^{st} contact structure is formed to have the extra isolation layer on a side surface thereof facing the 2^{nd} contact structure,
wherein the 1^{st} contact structure is formed to comprises:
a 1^{st} portion on a top surface of the 1^{st} source/drain pattern; and
a 2^{nd} portion vertically above the 1^{st} portion, and
wherein the extra isolation layer is not formed on a side surface of the 1^{st} portion.

26. The method of claim 25, wherein the 1^{st} portion and the 2^{nd} portion have different material compositions
